(19) United States
(12) Patent Application Publication
(10) Pub. No.: US 2009/0280989 A1
(43) Pub. Date: Nov. 12, 2009

(54) Control of Egress of Gas from a Cryogen Vessel

(75) Inventors: Eugene Astra, Oxford (GB); Trevor B. Husband, Banbury (GB); Nicholas Mann, Compton (GB); Philip Alan Charles Walton, Oxon (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Oxon (GB)

(21) Appl. No.: 12/463,867

(22) Filed: May 11, 2009

(30) Foreign Application Priority Data
May 12, 2008 (GB) 0808444.4

(51) Int. Cl. H01L 39/24; H01F 6/02; H01F 6/04

(52) U.S. Cl. 505/163; 174/15.4; 62/51.1

(57) ABSTRACT

A method for controlling egress of gas from a cryogen vessel (12) housing a superconducting magnet (10). A controller (30) receives data indicative of gas pressure within the cryogen vessel; a controlled valve (40) controls the egress of cryogen gas from the cryogen vessel (12); and data is made available to the controller, indicating a state of the magnet. Egress of cryogen gas from the cryogen vessel is controlled by operation of the controlled valve (40) by the controller (30) in response to the available data indicating a state of the magnet.

The present invention relates to control apparatus and methods for regulating gas pressures inside vessels and gas flow from vessels. It particularly relates to the control of gas pressure in, and flow of gas from, a cryogen vessel such as those known for cooling superconducting magnet coils in MRI imaging systems.

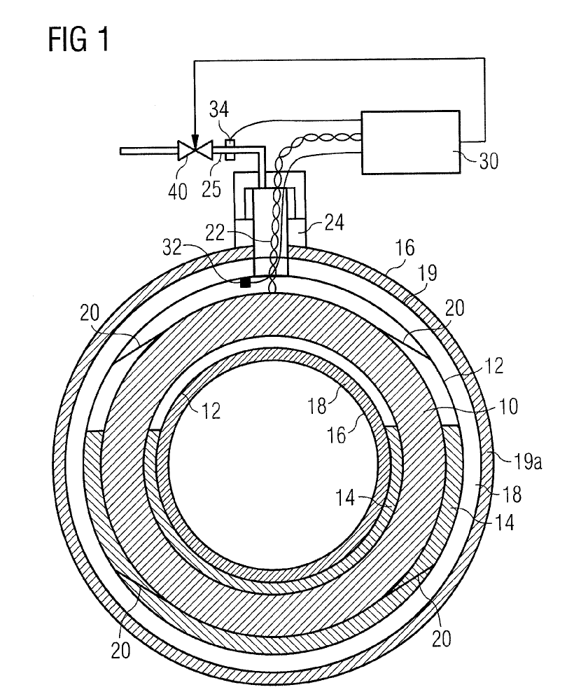

FIG. 1 schematically shows a cross-section of an MRI imaging magnet housed within a cryostat. As is well known in the art, such arrangements typically comprise a set of superconducting coils 10 mounted on a former (not shown), suspended in a cryogen vessel 12 which is partially filled with liquid cryogen 14. The liquid cryogen is selected such that its boiling point is below the superconducting transition temperature of the wire used in the coils 10. An outer vacuum container OVC 16 surrounds the cryogen vessel. The space 18 between the inner surface of the OVC and the outer surface of the cryogen vessel is evacuated, to reduce heat influx to the cryogen vessel by convection. One or more thermal radiation shields 19 may be provided in the evacuated space, to reduce thermal influx to the cryogen vessel by radiation. A solid thermal insulating layer such as aluminium coated polyester sheets 19a may also be provided within the evacuated space, to further reduce thermal influx. Careful design of support and suspension members 20 reduces heat influx to the cryogen vessel by conduction.

The coils 10 are provided with electrical current by current leads 22 leading into the cryogen vessel through an access turret 24. The process of introducing electrical current is known as ramping. The access turret typically also provides a venting path 25 for cryogen gas to escape. It is necessary to allow cryogen gas to escape for several reasons, depending on the state of operation of the magnet 10. The present invention relates to the equipment provided to allow such venting and the methods for controlling the venting of cryogen gas. Some examples of situations which require the venting of cryogen gas are as follows. During operation, the cryogen vessel 12 must remain sealed against air ingress, yet the gas pressure within the cryogen vessel must be accurately controlled to maintain the correct thermal environment for the superconducting coils. During ramping, an accurately controlled release of cold gas may be required, to cool the current leads 22.

In existing systems, control of cryogen gas venting during all normal operating conditions (cryogen fill, ramp, normal operation at field) is achieved using a direct-acting mechanical valve. Achieving the required control precision under these varying circumstances has proved difficult and expensive. Consequences of this poor control include less-than-ideal coil temperatures during ramping, with consequently increased risk of quench, and increased cryogen losses.

In known MRI imaging systems and the like, it is customary to provide a magnet supervisory system 30 which receives data from sensors 32, 34 and is in control of current flow in the magnet, and controls the operation of the magnet system for optimal performance at all times: during ramp-up, in steady state operation; during imaging and during ramp-down.

A further requirement is the need for a high degree of leak tightness in both directions. If cryogen gas leaks out of the cryogen vessel, unacceptable cryogen consumption will result, possibly leading to a warming of the magnet 10; this may result in a quench. If contaminants such as air or other gases leak into the cryogen, they may freeze into a solid deposit which may induce quench; or may obstruct an exit channel for boiled-off cryogen, which may be hazardous in the event of a quench. During quench, debris may be expelled from the magnet, and if this contaminates the seat of valve 26, unacceptable leakage can result in either direction.

The mechanical vent valves currently used depend on the balance of gas pressure and spring forces to modulate the opening of the valve's plate. The operating forces in a valve of this type are small, and consequently performance is sensitive to small changes in spring force, friction, operating temperature, and a range of manufacturing tolerances. Expensive calibration and conditioning techniques are used to reduce these effects, but despite this, pressure control performance is only just adequate for the application and reliability is poor.

Despite significant development efforts in the past, existing direct-acting mechanical vent valves (wherein the valve plate is directly operated by the spring/bellows system or similar) do not provide accurate or optimised control of cryogen vessel pressure for superconducting magnets for MR imaging, and similar apparatus. Due to demanding calibration requirements, such valves are also expensive to manufacture and unreliable in operation.

To avoid the risk of air/ice contamination of the cryogen vessel, the pressure within the cryogen vessel is normally maintained above atmospheric, for example by the magnet supervisory control system 30 controlling a cryogenic refrigerator in accordance with measured data from an absolute or gauge pressure transducer 32. However, during ramping, further pressure rise should be limited, in order to maintain acceptable magnet temperatures, by allowing increased boil-off of the liquid cryogen. As a result of these conflicting requirements, very precise control and measurement of cryogen vessel pressure is required to be provided by the vent valve 40 and the pressure control system, typically included within controller 30.

It has been found difficult to provide a mechanical valve system with effective and reliable on/off operation. Even a small amount of contamination on the valve element or valve seat may cause the valve to leak in the closed position. On the other hand, contamination may prevent the valve from opening completely. In either case, the valve may not maintain the required pressure within the vessel or permit the required gas flow rate from the vessel.

In alternative arrangements, venting is controlled by a valve fitted with an actuation device, which is controlled using an intelligent controller. With this arrangement it is possible to accurately control the pressure and vent gas flow rate. Such an arrangement is described, for example, in UK patent application GB2398874, particularly with reference to FIG. 6 and claim 15 of that document; and in International patent publication WO2006/021234.

With the use of such controlled valves, the need for an accurately calibrated valve is eliminated, as a self-compensating control loop may be effected. This allows chosen pressures to be reliably maintained within the cryogen vessel, and/or a venting of gas may be operated when an internal absolute or gauge pressure reaches a certain value. An accurate and predictable control of vent gas flow rate as required for operation of systems which include a cryogen vessel may similarly be provided.

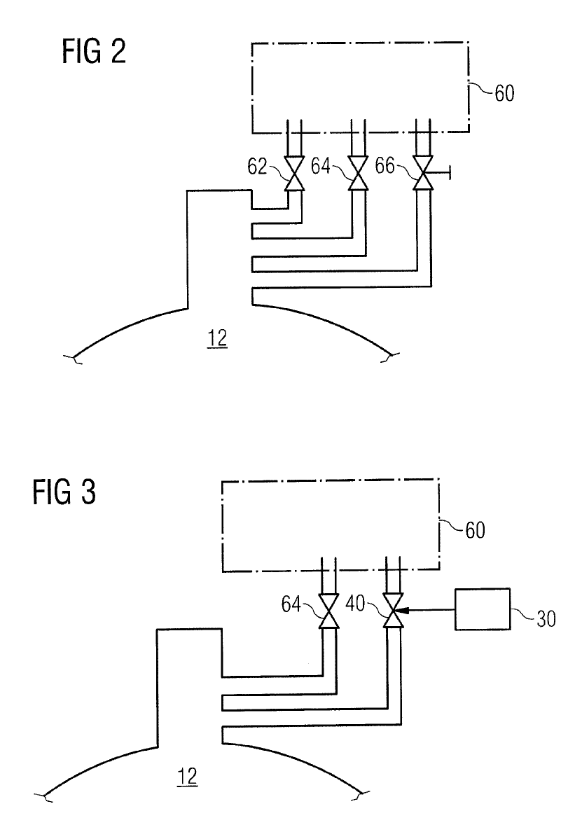

The function of the mechanical valve 26 may accordingly be replaced by a controlled valve 40, under the control of an intelligent control system such as the magnet supervisory control unit 30. Data inputs, available to the magnet supervisory control unit 30, may include absolute cryogen vessel pressure and/or cryogen vessel temperature. In the example illustrated in FIG. 2, sensors 32 and 34 provide data to the magnet supervisory unit 30 indicating the pressure within the cryogen vessel and the flow rate of gas venting from the cryogen vessel.

The controlled valve 40 may have a simple cyclic on/off function. Accurate pressure control is achieved by varying a duty cycle of the on/off state of the valve, eliminating the need for precise calibration of the valve. In such arrangements, the exact flow capacity of the valve is not particularly important, as the pressure measurement and duty cycle adjustment will compensate for minor variations. In some arrangements, magnet supervisory control system 30 controls the valve 40 so as to maintain a required pressure or a required gas flow rate by the controller changing the on-off time ratio (duty cycle) of cyclically opening and closing the controlled valve 40. By using a suitably dimensioned valve and operating frequency, the variation in pressure can be maintained within close limits.

For example, a very simple control method may operate along the lines of:
(1) set required absolute pressure within cryogen vessel=x;
(2) detect actual pressure p within cryogen vessel from sensor 32 conventionally provided;
(3) if p>x, increase “open” proportion of valve operation duty cycle; and
(4) if p<x, reduce “open” proportion of valve operation duty cycle.

Where control of gas flow rate is required, rather than gas pressure, the control method may resemble:
(1) set required gas flow rate from the cryogen vessel=R;
(2) detect actual gas flow rate r from the cryogen vessel from a sensor 34 conventionally provided;
(3) if r<R, increase “open” proportion of valve operation duty cycle; and
(4) if r>R, reduce “open” proportion of valve operation duty cycle.

Suitable control signals and suitable arrangements for modifying the control signals to provide the required operation may be simply derived by those skilled in the art. The exact signals and variation in the control signals chosen is not of particular importance to the present invention.

In an alternative arrangement, the controlled valve 40 may have a variable opening, which is controlled by the magnet supervisory control system 30. For example, a ball valve may be operably connected to a stepper motor which will rotate the valve ball to a position determined by signals sent to the stepper motor. The cross section of the available gas flow path may be varied by control of the valve 40, for example by operating an associated stepper motor, to obtain the desired effect, eliminating the need for precise calibration of the valve. The effect of such variation is monitored by sensors such as shown at 32 and 34. In such arrangements, the exact flow capacity of the valve is not particularly important, as the flow measurement and duty cycle adjustment will compensate for minor variations. For example, a very simple control method may operate along the lines of:
(1) set required absolute pressure within cryogen vessel=x;
(2) detect actual pressure p within cryogen vessel from sensor 32 conventionally provided;
(3) if p>x, increase cross section of the available gas flow path; and
(4) if p<x, reduce cross section of the available gas flow path.

Where control of gas flow rate is required, rather than gas pressure, the control method may resemble:
(1) set required gas flow rate from the cryogen vessel=R;
(2) detect actual gas flow rate r from the cryogen vessel from a sensor 34 conventionally provided;
(3) if r<R, increase cross section of the available gas flow path; and
(4) if r>R, reduce cross section of the available gas flow path.

Various control strategies are possible for the valve and may be defined in the software of the control unit. An advantage of the controlled valve arrangements is that imperfections in the valve hardware may be compensated for in the software of the magnet supervisory control system 30. One may employ data provided by such sensors to operate a controlled valve to control the absolute pressure inside the cryogen vessel as required. By providing an atmospheric pressure sensor, the gauge pressure of the interior of the cryogen vessel 12 may be controlled.

Control signals for valves operated by stepper motors, generated by the magnet supervisory control system 30 may easily be derived by those skilled in the art.

For current MRI imaging magnet systems, it has been found that a valve operating frequency of below 1 Hz is quite sufficient, given the size of the system. Greater frequencies of valve operation may be found necessary, particularly for much smaller cryogen tanks.

Of course, the described control method would most likely be operated as a computer program or the like. With such control arrangements, it is simple to vary the required pressure x or desired gas flow rate r.

The controlled valve 40 itself should be chosen to have a maximum flow capacity sufficient to accommodate the highest intended rate of cryogen gas outflow, typically during ramping, with a suitable modest pressure rise. However, the flow capacity of the valve should not be unnecessarily large at the risk of deteriorated control precision and sealing efficiency.

The use of cryogens, typically helium, represents a significant and increasing cost. Furthermore, helium is a finite consumable resource, and measures are now required to reduce consumption of helium.

FIG. 2 schematically represents a valve arrangement of a conventional cryostat arrangement employing direct-acting mechanical valves. Leading from the cryogen vessel 12 to atmosphere, or a cryogen recuperation facility 60, are three parallel valves 62, 64, 66.

First valve 62 is a passive safety protection valve. If the pressure within the cryogen vessel 12 exceeds a certain value, below a maximum safe value, the pressure will act upon a spring- or gravity-biased element of mechanical valve 62, or equivalent, to open it to a certain extent, allowing cryogen gas to escape from the cryogen vessel 12 into the atmosphere or recuperation facility 60. Once the pressure in the cryogen vessel drops below the certain value, the valve closes again. Typically, an under-pressure, that is a pressure below a certain threshold, typically the pressure of the atmosphere or recuperation facility 60, will act upon the element of valve 62 to hold it firmly closed, preventing or restricting ingress of gases from the atmosphere or recuperation facility 60 into the cryogen vessel 12.

Second valve 64 is a quench valve. When a quench occurs in a superconducting magnet housed within the cryogen vessel 12, a large amount of stored energy is rapidly released as heat, causing sudden boil-off of large quantities of cryogen, accompanied by a sudden rapid rise in cryogen vessel pressure. Such events are relatively rare, but the passive protection safety valve 62 is typically too small to cope. Quench valve 64 typically opens at a higher cryogen vessel pressure than the passive protection safety valve 62, and provides a much greater gas egress path cross-section. The quench valve is typically a spring-biased, direct-acting mechanical valve. When a pressure in the cryogen vessel reaches a sufficiently high pressure, the quench valve is forced open against the force of the spring to provide a large gas egress path, allowing venting of a large mass of cryogen and preventing the pressure within the cryogen vessel reaching a dangerous level. Of course, the passive protection safety valve 62 will also open, being activated at a lower pressure. There is a risk that the passive protection safety valve 62 may be contaminated or damaged by debris expelled from the cryogen vessel during a quench event. If the passive protection safety valve 62 is damaged or contaminated, it may either fail to close properly after the quench event, leading to uncontrolled loss of cryogen; or may fail to open when the pressure within the cryogen vessel again exceeds the certain value. The quench valve may be replaced by a burst disc. Rather than a spring-loaded valve element, the burst disc comprises a frangible seal closing the quench gas egress path. In the case of a quench, the burst disc will shatter, providing a gas egress path of large cross-sectional area. Once the quench event is over, the remains of the burst disc must be removed and a replacement disc installed. Such burst discs have the advantage of reduced tendency to leak as compared to mechanical quench valves.

Third valve 66 is a pressure control valve. This may be manually operated, either directly mechanically or by user intervention at a control system. This valve is used when a user wishes to deliberately reduce the pressure within the cryogen vessel. For example, a service engineer may need to reduce the pressure within the cryogen vessel 12 to atmospheric pressure before performing a service operation. With manually operated valves, there is a risk that the valve is left open for so long that the pressure within the cryogen vessel 12 falls below the pressure of the atmosphere or recuperation facility 60, allowing ingress of gases from the atmosphere or recuperation facility 60 into the cryogen vessel 12.

The present invention provides improved methods for controlling the pressure within the cryogen vessel, and rates of egress gas flow from the cryogen vessel, at various instants during operation of a magnet, as will now be described.

Accordingly, the present invention provides methods as defined in the appended claims.

The above, and further, objects, characteristics and advantages of the present invention will become clearer in consideration of the following description of certain embodiments, given by way of examples only, in conjunction with the accompanying drawings, wherein:

FIG. 1 shows a schematic cross-section of a cryostat containing a magnet for an MRI system according to the prior art;

FIG. 2 schematically represents a valve arrangement of a conventional cryostat arrangement employing direct-acting mechanical valves; and

FIG. 3 schematically represents a valve arrangement of a cryostat arrangement employed in the present invention.

FIG. 3 schematically represents a valve arrangement of a cryostat arrangement employed in the present invention, using a controlled valve 40. Features corresponding to those in FIG. 2 carry corresponding reference numerals. Controlled valve 40 is controlled by magnet supervisory control system 30 according to certain pressure and gas egress flow rate control methods, some of which form aspects of the present invention. In particular, the controlled valve 40 is arranged to provide a passive pressure control function, rendering the passive protection safety valve 62 of FIG. 2 unnecessary. The actively controlled valve 40 replaces both the bypass valve 66 and pressure control valve 62 of the known arrangement of FIG. 2, providing one single valve for two functions, rather than the previous arrangement of a valve for each function.

The controlled valve 40 is responsive to over-pressures within the cryogen vessel by opening by a certain extent to allow venting of cryogen gas, and is affected by an under-pressure in the cryogen vessel to hold it firmly closed, preventing or restricting ingress of gases from the atmosphere or recuperation facility 60 into the cryogen vessel 12. For example, the controlled valve 40 may be as described in the co-pending UK patent application GB0808442.8 filed of even date herewith by the present applicant.

As may be readily observed from a comparison of FIGS. 2 and 3, the use of controlled valve 40 as shown avoids the need for passive safety protection valve 62, simplifying the overall system.

According to aspects of the present invention, particular control methods are provided, operated by magnet supervisory control system 30 controlling valve 40. Performance of the methods of the invention may involve the execution of a computer program by the magnet supervisory control system 30. These methods may be applied by the magnet supervisory control system 30 as appropriate, and are preferably adapted to limit egress of cryogen to the atmosphere or recuperation facility 60.

The magnet supervisory system 30 receives data inputs indicating the state of operation of the magnet and/or data inputs indicating temperature and/or pressure within the cryogen vessel. The magnet supervisory system may also receive data inputs from a remote user over a telecommunications system. The magnet supervisory control system controls the valve 40 according to such input data.

The intelligent control of controlled valve 40 by magnet supervisory control system 30 allows improved control of the thermal environment of the coils. This improved control preferably acts to reduce the consumption of cryogen during normal operational situations, and further preferably acts to reduce the probability of quench, so reducing the likely cryogen loss. The controlled valve may be operated, according to methods of the present invention, to control gas egress flow rate, and so also to control the coil temperature. According to aspects of the present invention, the controlled valve may be operated to optimise pressure within the cryogen vessel and gas egress flow rates to minimise consumption of cryogen.

The methods of the present invention may control the valve 40 to exercise temperature control by controlling the pressure within the cryogen vessel. The pressure within the cryogen vessel may be controlled as a function of magnet operation, and/or as a function of atmospheric pressure.

Particular methods of the present invention will now be described in some detail.

### Extra Venting During Ramping

During introduction of electrical current into the magnet, known as ramp-up, temperature in the cryogen vessel rises, raising the pressure within the cryogen vessel, as the current leads heat up, causing an increased rate of cryogen boil-off.

Similarly, during removal of electrical current from the magnet, known as ramp-down, temperature in the cryogen vessel rises as current again flows through the resistive current leads. This raises the pressure within the cryogen vessel, as the current leads heat up, causing an increased rate of cryogen boil-off.

In the present description, the terms “ramping” and “ramp procedure” are to be understood as including both ramp-up and ramp-down.

Ramping of the magnet is typically controlled by the magnet supervisory control system 30. Accordingly, the magnet supervisory control system 30 may control the controlled valve 40 in accordance with an ongoing, or planned, ramp procedure. When a ramp procedure is about to start, or is in progress, the controlled valve 40 may be held fully open, or with a large “open” proportion of duty cycle; or with a large cross section of the available gas flow path, depending on the particular type of valve used. This ensures easy egress for the boiled-off cryogen, ensuring that the pressure within the cryogen vessel is low and that vent flow changes smoothly. This in turn ensures that temperature rises within the cryogen vessel are limited, and not abrupt, providing an optimised thermal environment for the magnet. A beneficial side-effect arises in that the boiled-off cryogen gas will cool the electrical current leads, as it leaves the cryogen vessel.

In the equivalent method using direct-acting mechanical valves, bypass valve 66 would be held open for the duration of the ramping procedure. However, this risked ingress of gases into the cryogen vessel and was not optimised in terms of cryogen consumption.

Alternatively, the magnet supervisory control system 30 may be provided with a data input indicating that ramping is in progress, which may be a simple voltage measurement at the current input leads; and data inputs indicating pressures within the cryogen vessel 12 and within the atmosphere or recuperation facility 60. The magnet supervisory control system 30 may control the controlled valve 40 according to the data input signalling whether ramping is in progress, and the data inputs indicating pressures within the cryogen vessel 12 and within the atmosphere or recuperation facility 60. While ramping is in progress, the magnet supervisory control system 30 may open the control valve 40 as far as possible while still maintaining a certain excess of pressure within the cryogen vessel as compared to the atmosphere or recuperation facility 60. Once ramping is over, as indicated to the magnet supervisory control system 30 by the corresponding data input, the magnet supervisory control system 30 may revert to a stable routine of operating the control valve 40 to maintain a certain pressure within the cryogen vessel 12.

### Limited Extra Venting During Ramping

Alternatively, rather than providing maximum gas egress flow during the whole ramping process, cryogen vessel pressure and gas egress flow may be controlled during ramping to provide maximum cooling at critical instants within the ramp procedure and a reduced, yet sufficient, cooling effect at other times. Such improved method would serve to further reduce cryogen consumption during the ramping procedure. As an example of such improvements, the opening of controlled valve 40 and the resulting gas flow rate can be chosen to generate an optimised pre-ramp cryogen flow for cooling the current leads. The magnet supervisory control system 30 acts to control the ramp procedure so may begin by generating a lead-cooling cryogen gas flow, even before ramping proper begins.

In addition, the coils of the magnet are subjected to changing forces due to the changing magnetic field strength and currents which they experience. Some movement of the coils may occur, as is known in itself. Additional cooling, provided at times when such heating or coil movement is likely, would be beneficial in reducing the probability of a quench.

Quench events are believed to be most likely to occur near the beginning of ramp-up, when a relatively high current is flowing into the magnet, and the coils may not be firmly in their operating positions.

According to methods of the present invention, the variation of cryogen vessel pressure with time during ramp may be optimised to provide cooling when required, while reducing the overall cryogen consumption. By building up an increased pressure within the cryogen, extra cooling to the magnet may be provided when reducing the cryogen vessel pressure. The cryogen gas released may be used to cool the current leads as it leaves the cryogen vessel.

Conventionally, the pressure within the cryogen vessel is kept constant, which does not allow for additional cooling to be generated when required, and results in relatively high cryogen consumption. In one method according to the present invention, the pressure within the cryogen vessel is initially maintained relatively high, then lowered at a later time, at which cooling is required. The relatively rapid reduction in cryogen vessel pressure causes a correspondingly relatively rapid fall in temperature, which may be timed to coincide with a heat-generating step of the ramping procedure, to provide more effective cooling, and reduced cryogen consumption, as compared to the conventional method. In an improved method of the present invention, a gradual, controlled reduction in pressure to a stable, reduced level is performed. The reduction in pressure causes extra cooling during ramp. By gradually reducing pressure, the increased cooling effect may be maintained for longer.

The temperature profile may accordingly be optimised during ramp to reduce the risk of quench, by reducing the risk of any part of the magnet increasing in temperature sufficiently to cease being superconducting. By measuring magnet current and cryogen gas temperature and/or pressure, a closed loop control method may be exercised.

### Avoiding Leakage During Normal Operation

During normal operation of the superconducting magnet, the magnet supervisory control system 30 may operate with a required pressure within the cryogen vessel 12 raised to a maximum tolerable value for normal operation, with the controlled valve 40 normally closed. Use of a controlled valve 40 allows reliable, rapid response to a detected excess pressure within the cryogen vessel 12, so it is possible to have a higher normal operating pressure within the cryogen vessel than was conventionally considered desirable. The pressure inside the cryogen vessel 12 is monitored by sensors 32 and the magnet supervisory control system 30, which will operate to open the controlled valve 40 if the pressure in the cryogen vessel 12 reaches the set limit value. Conventional pressure control methods relied upon the opening of a direct-acting mechanical valve to limit the maximum pressure within the cryogen vessel. To prevent those mechanical valves from leaking during normal operation, the normal operating pressure was kept significantly below the maximum pressure and the pressure required to open the mechanical valves, although cryogen leakage still occurred. With the method of the present invention used to operate a controlled valve 40, it is possible to reliably detect a relatively small increase in pressure and to react rapidly by opening, or increasing the opening of, the controlled valve 40. Leakage of cryogen is thereby reduced as compared to conventional pressure control methods.

The magnet supervisory control system may control pressure within the cryogen vessel by allowing cryogen gas to vent until a predetermined pressure is arrived at, and then closing the controlled valve 40. The magnet supervisory system may monitor a pressure sensor to ensure that the pressure in the cryogen vessel does not become sub-atmospheric, for example by controlling operation of a cryogenic refrigerator arranged to cool the interior of the cryogen vessel 12.

### Evacuating Boiled Off Gas During Imaging Sequences

During imaging sequences of an MRI system comprising a superconducting magnet 10, pulsed currents are caused to flow through gradient coils (not shown) to provide magnetic field gradients required for imaging. As a result of these pulsed currents and the resulting varying magnetic field, eddy currents may be induced in parts of the cryostat. These eddy currents may cause heating due to the electrical resistance of the cryostat. The gradient coils themselves may heat up due to the pulsed currents. Overall, the result is an increased thermal influx to the cryogen vessel 12 during imaging sequences. This in turn will raise the temperature and pressure of cryogen gas within the cryogen vessel 12 unless increased venting is provided. According to a method of the present invention, during periods when increased cryogen venting is required, for example during imaging procedures of an associated MRI system, the magnet supervisory control system 30 controls the controlled valve 40. Rather than simply responding to an increase in pressure within the cryogen vessel, the present invention allows increased cooling to be commenced before the imaging cycle causes the increased boil-off. As the magnet supervisory system 30 is in control of the imaging sequence, then it can, according to an embodiment of the present invention, operate controlled valve 40 to reduce pressure within the cryogen vessel 12 before, or at the same time that the imaging sequence causes increased boil-off.

### Controlled Valve Held Closed During Quench for Own Protection

In a quench event, a very large mass of cryogen escapes in a very short time. The conventional arrangement of mechanically controlled valves, urged into a closed position by a suitable bias spring, so as to open when a required limit pressure is exceeded, may suffer during such an event. During a quench, the cryogen vessel pressure will rise sharply, and simple spring-loaded mechanical valves would open. The likelihood of valve seat contamination from debris expelled from the cryogen vessel is relatively high. Other damage to the valve is also likely, particularly to resilient valve seals.

It is conventional to provide cryogen vessels containing superconducting coils with a separate quench valve which is a simple spring-loaded valve. In case of a quench, this valve will open to carry the high flow rate caused by the quench, and is quite sufficient. According to a method of the present invention, controlled valve 40 is held in its closed position during a quench event, by the control system 30, thus avoiding the risk of debris contamination of the valve seat or other damage to the controlled valve 40. The onset of a quench event can be detected by the magnet supervisory control system 30 as indicated by sensors conventionally provided within the cryogen vessel, as known by those skilled in the art. In response to the detection of the onset of the quench event, the magnet supervisory control system 30 closes the controlled valve 40 completely. The quench valve, which will be opened by the quench event, will be sufficient to allow egress of cryogen as necessary. By holding the controlled valve 40 closed, valve-seat contamination, and other damage, to controlled valve 40 is prevented. The advantageous effect of avoiding valve-seat contamination during quench would not be possible with the simple mechanical spring-loaded valves of the prior art, since they would also open in a quench event due to the increased pressure within the cryogen vessel.

In an alternative, or complementary, method, the controlled valve 40 may be arranged as a safety valve, and be fully or largely opened in response to the detection of an excessive pressure within the cryogen vessel. For example, a very high pressure may indicate that the quench valve or burst disc has failed to open, and that at least some venting may be provided by opening the controlled valve.

### Remote Servicing Preparation

A situation in which the present invention is of particular utility is in the preparation of cryogen vessels for servicing. Such operations will now be discussed, with particular reference to the servicing of magnets of MRI imaging systems housed within cryogen vessels. However, such operations and advantages may be applied to situations in which other types of equipment are accommodated within a cryogen vessel.

As mentioned earlier, the pressure within the cryogen vessel is typically maintained above atmospheric during normal operation of the magnet. Before a service engineer can work on the magnet 10, the pressure within the cryogen vessel 12 must be reduced to atmospheric. Conventionally, this is carried out as follows. A service engineer arrives on site and manually opens a bypass valve 66 to open vent path 25. The vent path is left open, with gaseous cryogen venting to atmosphere or recuperation facility 60, until the gas pressure within the cryogen vessel has dropped to atmospheric (gauge pressure=0). This usually takes about 30 minutes with presently known systems. It represents a significant consumption of cryogen, and an inefficient use of the service engineer's time.

In certain embodiments of the present invention, operation of the valve 40 is remotely controlled. For example, the magnet supervisory control system 30 may be connected to a network such as the Internet or the telephone system, or a private network, to receive commands over such network. This is of particular use, for example, to service personnel who may remotely command the controlled valve 40 to place the cryogen vessel in a certain state in time for the arrival of service personnel on site. This enables the service personnel to save time and improve their productivity, as the cryogen vessel will be ready for servicing on their arrival. Service costs for the owner/operator of the cryogen vessel and associated equipment may be reduced. As the depressurisation step is remotely controlled, it need not be performed as rapidly as is conventional. Slow de-pressurisation (e.g. over several hours) is now possible without wasting service engineer time. Furthermore, slow depressurisation will make better utilisation of the latent heat of vaporisation in cooling the magnet, so reducing cryogen loss in venting.

Controlled opening may reduce or eliminate the “flash losses” previously encountered with manual depressurisation, so reducing cryogen consumption.

While the present invention has been described with reference to methods each addressing a separate stage in the use of a cryogenically cooled magnet for an imaging system, each of the methods of the present invention share the features that they seek to improve the control of venting of cryogen gas from the cryogen vessel so as to reduce the consumption of cryogen by controlling venting in response to data available to the magnet supervisory control system, indicating the state of the magnet, rather than features of the cryogen gas, such as temperature, pressure and flow rate.

The data indicating a state of the magnet may be generated by the controller, as part of its function of controlling operation of the magnet; or may be made available to the controller by sensors associated with the magnet; or may be made available to the controller by electrical connections to parts of the magnet.

In certain embodiments, the controlled valve includes a valve element which is directly operated by a solenoid coil. In alternative embodiments, for example, a motor actuated ball valve or a pneumatically activated valve may be employed. The precise type of valve used is not essential to the present invention.

1. A method for controlling egress of gas from a cryogen vessel housing a superconducting magnet, wherein:
a controller receives data indicative of gas pressure within the cryogen vessel;
a controlled valve controls the egress of cryogen gas from the cryogen vessel; wherein
data is made available to the controller, indicating a state of the magnet, and that egress of cryogen gas from the cryogen vessel is controlled by operation of the controlled valve by the controller in response to the available data indicating a state of the magnet.

2. A method according to claim 1, wherein the controller controls the valve by cyclically opening and closing the controlled valve with a variable duty cycle.

3. A method according to claim 1 wherein the controller controls the valve by partially opening the valve to provide a gas flow path having a cross section of a controlled proportion of the cross section of the gas flow path provided when the valve is in a fully open position.

4. A method according to claim 1, wherein, in response to the data indicating the state of the magnet indicating that ramping of current into the magnet is in progress, or is about to start, the controller controls the valve to be fully open, or with a large “open” proportion of duty cycle; or with a large open proportion of the cross section of the gas flow path.

5. A method according to claim 4, wherein, during ramping of current into the magnet, gas egress from the cryogen vessel is controlled by the controller controlling the valve to provide additional cooling by reducing a gas pressure within the cryogen vessel at one or more certain instant(s) within the ramp procedure.

6. A method according to claim 1, wherein, during ramping of current into the magnet, gas egress from the cryogen vessel is controlled by the controller controlling the valve to provide additional cooling by gradually reducing a gas pressure within the cryogen vessel during the ramp procedure.

7. A method according to claim 1, wherein, in response to the data indicating the state of the magnet indicating normal steady-state operation of the magnet, the controller controls the valve such that the valve stays closed, unless the pressure reaches a set limit value as indicated to the controller.

8. A method according to claim 1, wherein, in response to the data indicating the state of the magnet indicating a current or planned imaging sequence, the controller controls the valve to reduce a pressure within the cryogen vessel, to provide a cooling effect to counteract an influx of heat into the cryogen vessel caused by the imaging procedure.

9. A method according to claim 1, wherein, in response to the data indicating the state of the magnet indicating onset of a quench, the controller controls the valve such that the valve stays closed, and cryogen vents through a parallel quench valve.

10. A method according to claim 9, wherein, in response to data indicating an excessively high pressure within the cryogen vessel during the quench event, the controller controls the valve to open to provide venting of cryogen from the cryogen vessel.

11. A method according to claim 1, wherein the data indicating a state of the magnet is generated by the controller as part of its function of controlling operation of the magnet.

12. A method according to claim 1, wherein the data indicating a state of the magnet is made available to the controller by sensors associated with the magnet.

13. A method according to claim 1, wherein the data indicating a state of the magnet is made available to the controller by electrical connections to parts of the magnet.

14. A method according to claim 1, wherein, in response to the data indicating the state of the magnet indicating that a service operation is to be performed, the controller controls the valve to reduce the pressure within the cryogen vessel to approximately atmospheric pressure, while ensuring that the pressure within the cryogen vessel does not drop below atmospheric pressure.

15. A method according to claim 14 wherein the data indicating the state of the magnet indicating that a service operation is to be performed is received from a remote location.

16. A method according to claim 14 wherein the data indicating the state of the magnet indicating that a service operation is to be performed is supplied remotely and is received over a telecommunications network.
